(19) United States
(12) Patent Application Publication
(10) Pub. No.: US 2023/0395309 A1
(43) Pub. Date: Dec. 7, 2023

(54) ELECTRONIC COMPONENT AND METHOD OF MANUFACTURING ELECTRONIC COMPONENT

(71) Applicant: Murata Manufacturing Co., Ltd., Kyoto-fu (JP)

(72) Inventors: Yoshimasa YOSHIOKA, Nagaokakyo-shi (JP); Ryuichiro TOMINAGA, Nagaokakyo-shi (JP); Takaaki MIZUNO, Nagaokakyo-shi (JP); Toshiyuki NAKAISO, Nagaokakyo-shi (JP)

(73) Assignee: Murata Manufacturing Co., Ltd., Kyoto-fu (JP)

(21) Appl. No.: 18/327,756

(22) Filed: Jun. 1, 2023

(30) Foreign Application Priority Data
Jun. 6, 2022 (JP) 2022-091780

(51) Int. Cl. H01F 27/29; H01F 41/04; H01F 27/32

(52) U.S. Cl. CPC H01F 27/292; H01F 41/042; H01F 27/324; H01L 28/60; H01F 2027/329

(57) ABSTRACT

An electronic component includes a semiconductor substrate having a main surface and containing a semiconductor material, and a coil provided on the main surface and composed of a conductive material. The semiconductor substrate includes a low-resistance portion having a lower electrical resistance than a semiconductor composed of the semiconductor material. The coil is electrically connected to the low-resistance portion. An axial direction of the coil is parallel to the main surface.

### CROSS-REFERENCE TO RELATED APPLICATION

This application claims benefit of priority to Japanese Patent Application No. 2022-091780, filed Jun. 6, 2022, the entire content of which is incorporated herein by reference.

### BACKGROUND

### Technical Field

The present disclosure relates to an electronic component and a method of manufacturing an electronic component.

### Background Art

Japanese Unexamined Patent Application Publication No. 2020-145475 discloses an electronic component of the related art. The electronic component includes a substrate having a first surface and a second surface, which face each other, a capacitor element formed on the first surface using a thin-film process, and a coil formed on the second surface.

### SUMMARY

When a capacitor element is formed using a thin-film process, as in Japanese Unexamined Patent Application Publication No. 2020-145475, it is conceivable that the substrate will be a semiconductor substrate having high affinity for the thin-film process. However, in the electronic component disclosed in Japanese Unexamined Patent Application Publication No. 2020-145475, the axis of the coil is perpendicular to a main surface of the substrate, and the magnetic flux generated by the coil passes through the substrate. In the case of a semiconductor substrate having a relatively low electrical resistance, eddy currents generated in the substrate by the magnetic flux passing through the substrate become larger, and this results in increased loss. In particular, if the semiconductor substrate is provided with a low-resistance portion formed by impurity doping or the like, the loss will be even greater.

Accordingly, the present disclosure provides an electronic component that can reduce loss due to eddy currents.

Therefore, an electronic component according to an aspect of the present disclosure includes a semiconductor substrate having a main surface and containing a semiconductor material, and a coil provided on the main surface and composed of a conductive material. The semiconductor substrate includes a low-resistance portion having a lower electrical resistance than a semiconductor composed of the semiconductor material. The coil is electrically connected to the low-resistance portion. An axial direction of the coil is parallel to the main surface.

Here, the “semiconductor material” is, for example, a single semiconductor composed of a Group IV element such as Si, a semiconductor composed of a Group III or Group V compound such as GaAs, SiC, GaN, or InP, or an oxide semiconductor such as ITO.

According to this aspect, the axial direction of the coil is parallel to the main surface, and as a result, the proportion of the magnetic flux generated by the coil that passes through the substrate can be reduced. Therefore, even if the electronic component includes a semiconductor substrate that contains a semiconductor material and a low-resistance portion, the loss due to eddy currents can be reduced.

The electronic component may further include an organic insulating layer composed of an organic insulating material and an inorganic insulating layer composed of an inorganic insulating material.

With this configuration, since the electronic component includes an organic insulating layer and an inorganic insulating layer, the degree of freedom when designing the electronic component is improved.

In the electronic component, the inorganic insulating layer may be an inorganic insulating layer located at least between the semiconductor substrate and the coil.

With this configuration, the thickness of the insulating layer located between the semiconductor substrate and the coil can be reduced.

In the electronic component, the organic insulating layer may be located in at least one out of between adjacent turns of the coil and in an inner diameter part of the coil.

With this configuration, since the unevenness of the outer shape of the coil can be filled with the organic insulating layer, the outer surface of the electronic component can be made flat.

The electronic component may further include a first external terminal that is electrically connected to the coil and provided along a plane parallel to the main surface.

With this configuration, the electronic component can be easily mounted on motherboard boards, package boards, and so on.

In the electronic component, the first external terminal is preferably positioned inside an outer edge of the main surface when viewed in a direction perpendicular to the main surface.

This configuration helps prevent a cutting blade from contacting the first external terminal when individual electronic components are being formed via cutting, and thus helps prevent deformation and burring of the first external terminal.

In the electronic component, the low-resistance portion may be exposed from at least part of an outer surface of the semiconductor substrate. The electronic component may further include a second outer terminal that is provided on a part of the outer surface where the low-resistance portion is exposed and that is connected to the low-resistance portion.

With this configuration, the low-resistance portion and the second external terminal can be used together as an external terminal of the coil. Therefore, the electrical resistance of the external terminal of the coil can be reduced compared to a case where the second external terminal is not provided.

In the electronic component, the second outer terminal may be provided along a plane parallel to the main surface.

With this configuration, the electronic component can be easily mounted on motherboard boards, package boards, and so on.

In the electronic component, the second external terminal may be positioned inside an outer edge of the main surface when viewed in a direction perpendicular to the main surface.

This configuration helps prevent a cutting blade from contacting the second external terminal when individual electronic components are being formed via cutting, and thus helps prevent deformation and burring of the second external terminal.

In the electronic component, the coil may include a first inductor wiring extending along the main surface and a second inductor wiring extending along the main surface and electrically connected to the first inductor wiring. The first inductor wiring and the second inductor wiring may be disposed side by side in a direction perpendicular to the main surface. A distance between the first inductor wiring and the second inductor wiring in a direction perpendicular to the main surface may be less than a thickness of the first inductor wiring in a direction perpendicular to the main surface.

With this configuration, the thickness of the electronic component in a direction perpendicular to the main surface can be reduced, and therefore the electronic component can be reduced in size.

In the electronic component, the coil may further include a connection wiring that connects the first inductor wiring and the second inductor wiring to each other, and the connection wiring may extend in a direction perpendicular to the main surface.

According to this configuration, the electronic component further includes a connection wiring that connects the first inductor wiring and the second inductor wiring to each other. Increasing the length of the connection wiring in the extension direction allows the volume of an inner magnetic path of the coil to be increased, and this results in an increase in the Q value of the coil. However, increasing the length of the connection wiring in the extension direction also increases the electrical resistance of the coil. With this configuration, since the connection wiring extends in a direction perpendicular to the main surface, the first inductor wiring and the second inductor wiring can be connected to each other across the shortest distance. Therefore, even when the length of the connection wiring in the extension direction is increased, the volume of the inner magnetic path of the coil can be increased while suppressing an increase in the electrical resistance of the coil. As a result, the Q value of the coil can be increased.

In the electronic component, the semiconductor substrate may be entirely constituted by the low-resistance portion.

With this configuration, the electrical resistance of the electronic component can be reduced.

In the electronic component, the low-resistance portion may be exposed from at least part of the main surface. The electronic component may further include a dielectric portion provided on the low-resistance portion and an electrode portion provided on the dielectric portion. A capacitor element may be formed by the low-resistance portion, the dielectric portion, and the electrode portion.

With this configuration, since the capacitor element is additionally provided, a composite electronic component such as an LC filter can be obtained.

In the electronic component, the coil may include a first inductor wiring extending along the main surface and a second inductor wiring extending along the main surface and electrically connected to the first inductor wiring. The first inductor wiring and the second inductor wiring may be disposed side by side in a direction perpendicular to the main surface. A thickness of the electrode portion in a direction perpendicular to the main surface may be less than a thickness of the first inductor wiring in a direction perpendicular to the main surface.

With this configuration, a small-sized electronic component can be obtained even when a capacitor element is additionally provided.

In the electronic component, part of the semiconductor substrate may be constituted by the low-resistance portion. The semiconductor substrate may include a diode element in a region other than a region where the low-resistance portion is disposed.

With this configuration, an electronic component including a diode element can be obtained.

The electronic component may further include a wiring portion that is composed of a conductive material identical to a conductive material constituting the coil and is electrically isolated from the coil.

With this configuration, the wiring portion allows an element that is electrically isolated from the coil to be formed.

A method of manufacturing the electronic component may include a step of forming the low-resistance portion in the semiconductor substrate, and a step of forming the coil after forming the low-resistance portion.

With this configuration, the step of forming the low-resistance portion, which has a high heat load, is performed before the step of forming the coil, and therefore the coil is not subjected to an unnecessary heat load. This enables an electronic component that can improve quality to be manufactured. In addition, when forming the coil, heat-sensitive organic materials and the like can be used, resulting in improved freedom of design.

An electronic component according to an aspect of the present disclosure can realize reduced loss due to eddy currents.

### BRIEF DESCRIPTION OF THE DRAWINGS

FIG. 1 is a plan view illustrating an electronic component according to a First Embodiment;

FIG. 2A is a sectional view taken along line A-A in FIG. 1;

FIG. 2B is a sectional view taken along line B-B in FIG. 1;

FIG. 3A is an explanatory diagram for explaining a method of manufacturing an electronic component;

FIG. 3B is an explanatory diagram for explaining a method of manufacturing an electronic component;

FIG. 3C is an explanatory diagram for explaining a method of manufacturing an electronic component;

FIG. 3D is an explanatory diagram for explaining a method of manufacturing an electronic component;

FIG. 3E is an explanatory diagram for explaining a method of manufacturing an electronic component;

FIG. 3F is an explanatory diagram for explaining a method of manufacturing an electronic component;

FIG. 3G is an explanatory diagram for explaining a method of manufacturing an electronic component;

FIG. 3H is an explanatory diagram for explaining a method of manufacturing an electronic component;

FIG. 3I is an explanatory diagram for explaining a method of manufacturing an electronic component;

FIG. 3J is an explanatory diagram for explaining a method of manufacturing an electronic component;

FIG. 3K is an explanatory diagram for explaining a method of manufacturing an electronic component;

FIG. 4 is a plan view illustrating an electronic component according to a Second Embodiment;

FIG. 5 is a sectional view taken along line A-A in FIG. 4;

FIG. 6 is a sectional view illustrating an electronic component according to a Third Embodiment;

FIG. 7 is a plan view illustrating an electronic component according to a Fourth Embodiment;

FIG. 8A is a sectional view taken along line A-A in FIG. 7;

FIG. 8B is a sectional view taken along line B-B in FIG. 7;

FIG. 9A is an explanatory diagram for explaining a method of manufacturing an electronic component;

FIG. 9B is an explanatory diagram for explaining a method of manufacturing an electronic component;

FIG. 9C is an explanatory diagram for explaining a method of manufacturing an electronic component;

FIG. 9D is an explanatory diagram for explaining a method of manufacturing an electronic component;

FIG. 9E is an explanatory diagram for explaining a method of manufacturing an electronic component;

FIG. 9F is an explanatory diagram for explaining a method of manufacturing an electronic component;

FIG. 9G is an explanatory diagram for explaining a method of manufacturing an electronic component;

FIG. 9H is an explanatory diagram for explaining a method of manufacturing an electronic component;

FIG. 9I is an explanatory diagram for explaining a method of manufacturing an electronic component;

FIG. 9J is an explanatory diagram for explaining a method of manufacturing an electronic component;

FIG. 9K is an explanatory diagram for explaining a method of manufacturing an electronic component;

FIG. 10 is a sectional view illustrating an electronic component according to a Fifth Embodiment; and

FIG. 11 is a sectional view illustrating an electronic component according to a Sixth Embodiment.

### DETAILED DESCRIPTION

Hereinafter, electronic components and methods of manufacturing electronic components according to modes of the present disclosure will be described using illustrated embodiments. The drawings include schematic drawings and do not necessarily reflect the actual dimensions and proportions.

### First Embodiment

Configuration

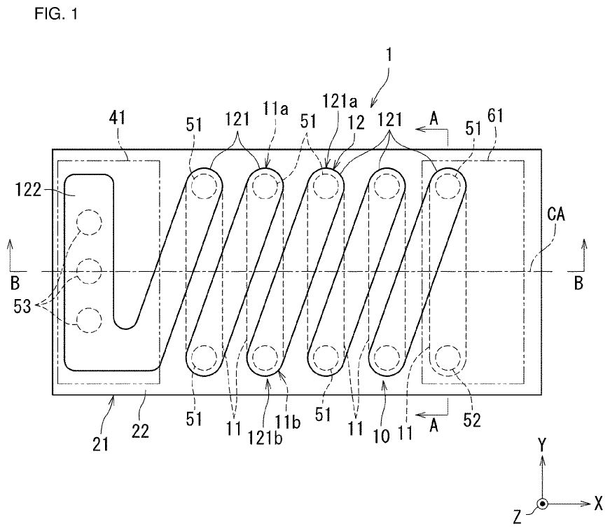

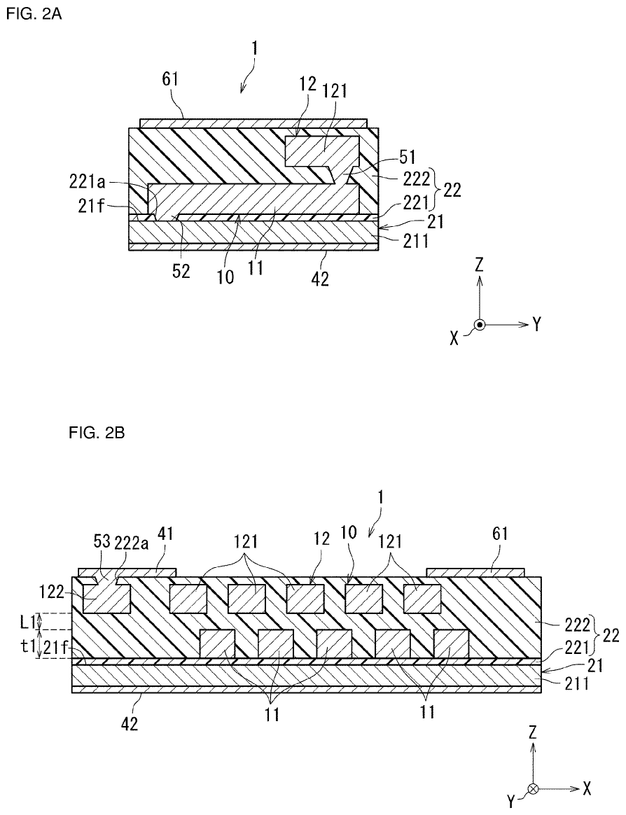

FIG. 1 is a plan view illustrating an electronic component according to a First Embodiment. FIG. 2A is a sectional view taken along line A-A in FIG. 1. FIG. 2B is a sectional view taken along line B-B in FIG. 1.

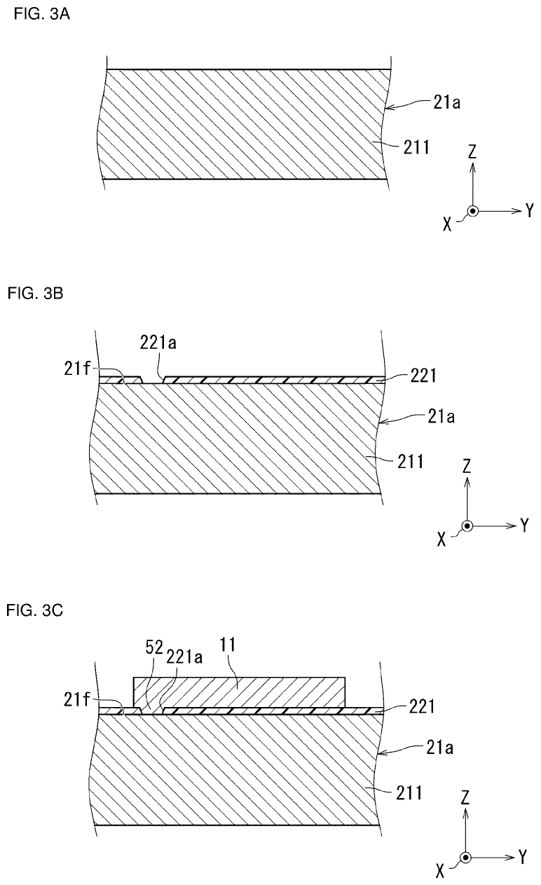

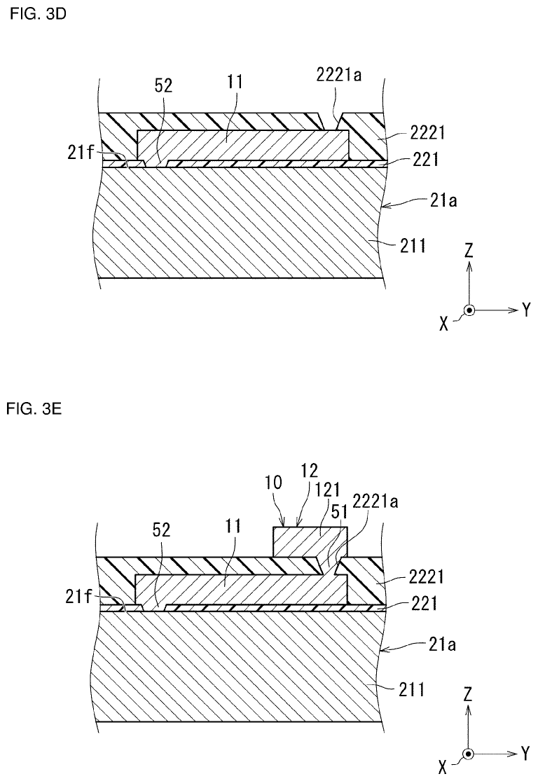

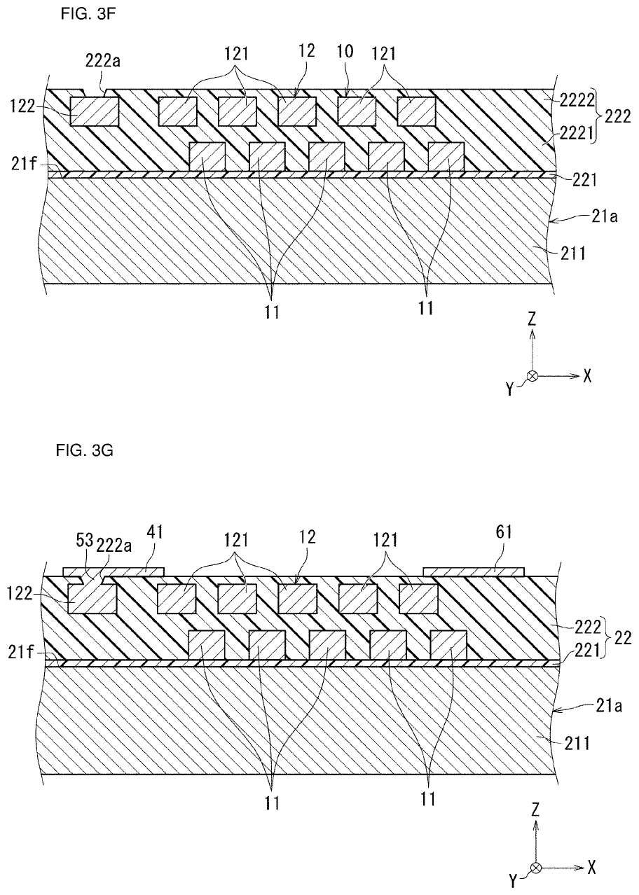

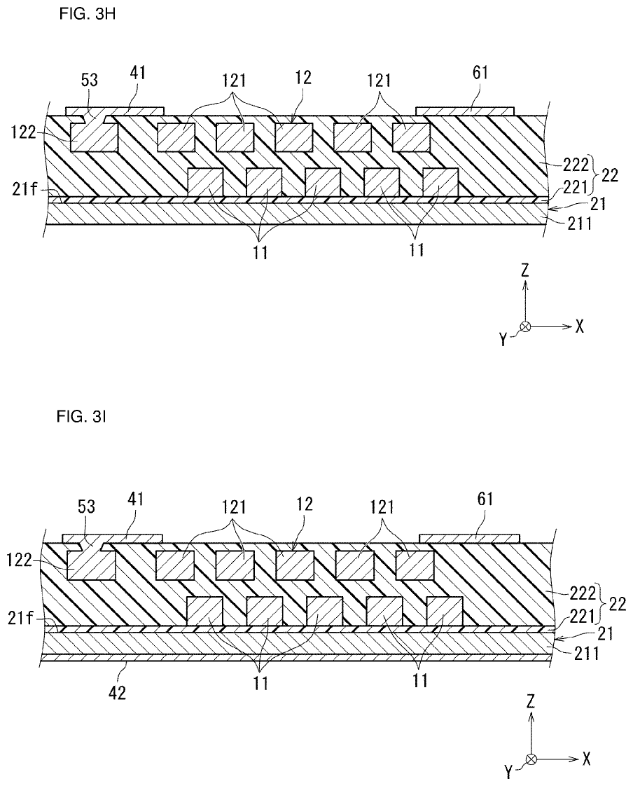

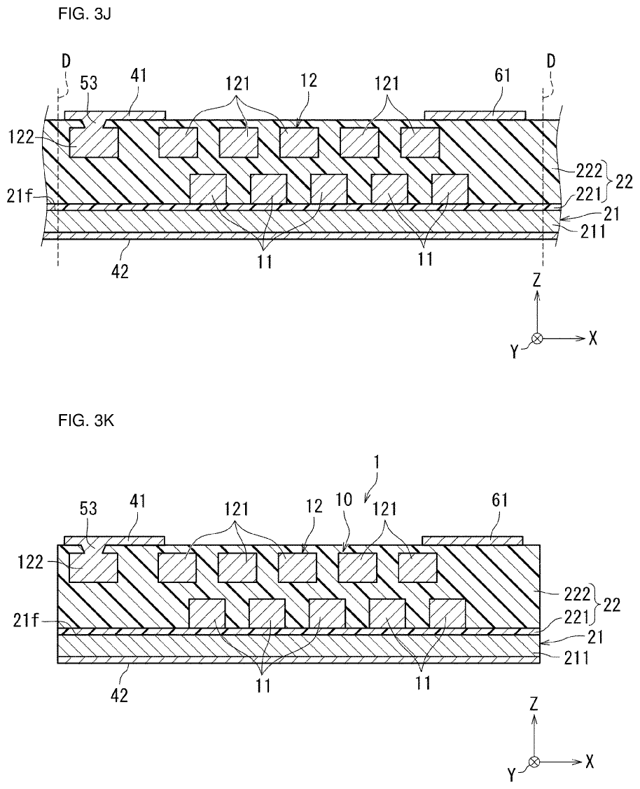

As illustrated in FIG. 1, FIG. 2A, and FIG. 2B, an electronic component 1 includes a semiconductor substrate 21 having a main surface 21f and containing a semiconductor material, an insulating layer 22 provided on the main surface 21f, a coil 10 provided inside the insulating layer 22 and on the main surface 21f and composed of a conductive material, a first external terminal 41 and a first dummy external terminal 61 provided on an upper surface of the insulating layer 22, and a second external terminal 42 provided on a lower surface of the semiconductor substrate 21. In FIG. 3, the first external terminal 41 and the first dummy external terminal 61 are represented by double-dotted chain lines for convenience.

In the figures, the thickness direction of the electronic component 1 is illustrated as a Z direction with the positive Z direction being the direction towards the upper side and the negative Z direction being the direction toward the lower side. In a plane of the electronic component 1 perpendicular to the Z direction, the length direction of the electronic component 1 is illustrated as an X direction and the width direction of the electronic component 1 is illustrated as a Y direction. The expression “on the main surface” does not refer to one absolute direction, such as vertically upward as defined by the direction of gravity, but rather to a direction towards the outside, regarding regions outside and inside the substrate, which is bounded by the main surface. Therefore, “on the main surface” is a relative direction determined by the orientation of the main surface. In addition, “on” a certain element includes not only a position directly on and in contact with the element (i.e., on), but also a position above the element at a distance from the element, i.e., a position above the element with another object on the element interposed therebetween or a position above the element at a distance from the element (i.e., above).

The semiconductor substrate 21 contains a semiconductor material such as a single semiconductor such as Si, a compound semiconductor such as GaAs, SiC, GaN, or InP, or an oxide semiconductor such as ITO. The semiconductor substrate 21 preferably contains Si. The shape of the semiconductor substrate 21 is not particularly limited, but is a rectangular parallelepiped shape in this embodiment. The main surface 21f is one of the six surfaces making up the outer surface of the semiconductor substrate 21 and faces in the positive Z direction.

The semiconductor substrate 21 includes, in at least part thereof, a low-resistance portion 211 containing the above semiconductor material and having a lower electrical resistance than a semiconductor composed of a semiconductor material, for example, Si, GaAs, SiC, GaN, InP, or ITO. In this embodiment, the entire semiconductor substrate 21 is constituted by the low-resistance portion 211. This enables the electrical resistance of the electronic component 1 to be lowered.

When the semiconductor substrate 21 contains, for example, Si as a semiconductor material, the low-resistance portion 211 is composed of Si doped with P or B. When semiconductor substrate 21 contains, for example, GaAs as a semiconductor material, the low-resistance portion 211 is composed of GaAs doped with Si, Sn, S, Se, Te, Be, Zn or Ge.

“Low resistance” means that the electrical resistivity is 10⁻¹ Ω·cm or less. This ensures that the electrical resistance of the low-resistance portion 211 is sufficiently low and the majority of the current is able to flow through the low-resistance portion 211. For example, if the semiconductor substrate 21 is a Si substrate, the electrical resistivity of the Si substrate is around 10³ Ω·cm. If the electrical resistivity of the low-resistance portion 211 is less than or equal to 1/1000 times the electrical resistivity of the portions of the semiconductor substrate 21 other than the low-resistance portion 211, the majority of the current can flow through the low-resistance portion 211. Therefore, the electrical resistivity of the low-resistance portion 211 is less than or equal to 10⁻¹ Ω·cm. The electrical resistivity of the low-resistance portion 211 can be calculated in the following way, for example. First, the DC electrical resistance is measured using a four-terminal method by bringing measurement probes into contact with both ends of the low-resistance portion 211. The electrical resistivity can then be measured by multiplying the measured electrical resistance by the cross-sectional area of the low-resistance portion 211, for example, the cross-sectional area of Si doped with phosphorus or boron, and then dividing the result by the length between the two ends of the low-resistance portion 211. The doped cross-sectional area can be calculated by exposing a cross section of the low-resistance portion 211 and performing element mapping using energy dispersive X-ray analysis (EDX). Specifically, the doped cross-sectional area may be the area of a region corresponding to 30% of the peak doping amount in the elemental mapping.

The low-resistance portion 211 can be obtained by doping the semiconductor substrate 21 with an impurity to form a high-concentration impurity region (in other words, a doped layer). In other words, the low-resistance portion 211 contains the semiconductor material contained in the semiconductor substrate 21, has a lower electrical resistance than a semiconductor composed of semiconductor material, and is integrated with the semiconductor substrate 21. If the semiconductor substrate 21 is a Si substrate, the semiconductor substrate 21 is preferably doped with a Group III or V impurity at around 1×10²⁰/cm³. As a result, the electrical resistivity of the low-resistance portion 211 is around 10⁻³ Ω·cm when doped with phosphorus, which is a Group V impurity, and is around 5×10⁻³ Ω·cm when doped with boron, which is a Group III impurity.

The insulating layer 22 protects the coil 10 from the external environment. The insulating layer 22 includes a first-layer insulating layer 221 on the main surface 21f and a second-layer insulating layer 222 provided on the first-layer insulating layer 221. The insulating layer 22 contacts at least part of the coil 10. This suppresses a leakage current from the coil 10 and increases the Q value. In this embodiment, the insulating layer 22 is in contact with the entire outer surface of the coil 10.

The first-layer insulating layer 221 is preferably an inorganic insulating layer composed of an inorganic insulating material such as a silicon oxide film, a silicon nitride film, or a silicon oxynitride film. When the semiconductor substrate 21 is, for example, a silicon substrate, the first-layer insulating layer 221 is preferably composed of thermally oxidized silicon (SiO₂) formed by thermally oxidizing the semiconductor substrate 21. However, the first-layer insulating layer 221 is not limited to this composition, and alternatively, a silicon oxide film may be formed on the main surface 21f of the semiconductor substrate 21 using a thin-film method such as sputtering or vapor deposition. An opening 221a is provided in the first-layer insulating layer 221 in a connection portion between the coil 10 and the low-resistance portion 211. The first-layer insulating layer 221 is preferably located at least between the semiconductor substrate 21 and the coil 10. This allows the thickness of the insulating layer located between the semiconductor substrate 21 and the coil 10 to be reduced.

The thickness of the first-layer insulating layer 221 is not particularly limited, but is 1 μm, for example. The material constituting the first-layer insulating layer 221 is not limited to the materials listed above, and may be composed of an organic insulating material such as epoxy resin, phenol resin, polyimide resin, liquid crystal polymer, or a combination of these materials, may be composed of a sintered material such as glass or alumina, or may be a combination of an inorganic insulating material and an organic insulating material.

The second-layer insulating layer 222 is preferably an organic insulating layer composed of an organic insulating material such as epoxy resin, phenol resin, polyimide resin, liquid crystal polymer or a combination of any of these materials. Openings 222a are provided in the second-layer insulating layer 222 in a connection portion between the first external terminal 41 and the coil 10. The second-layer insulating layer 222 is preferably located in at least one out of between adjacent turns of the coil 10 and in an inner diameter portion of the coil 10. This makes it possible to make the outer surface of the electronic component 1 flat because the unevenness of the outer shape of the coil 10 can be filled with the organic insulating material.

The thickness of the second-layer insulating layer 222 is not particularly limited, but is 10 μm, for example. The material constituting the second-layer insulating layer 222 is not limited to the materials listed above, and may be, for example, a sintered material such as glass or alumina, a thin film of an inorganic insulating material such as a silicon oxide film, a silicon nitride film, or a silicon oxynitride film, or a combination of an inorganic insulating material and an organic insulating material.

The coil 10 includes first inductor wirings 11, a second inductor wiring 12, and multiple first connection wirings 51 connecting the first inductor wirings 11 and the second inductor wiring 12 to each other.

The first inductor wirings 11 extend along the main surface 21f. There are multiple first inductor wirings 11. Specifically stated, each first inductor wiring 11 extends in a straight line in the negative Y direction from a first end portion 11a thereof to a second end portion 11b thereof. The lower surfaces of the first inductor wirings 11 are in contact with the upper surface of the first-layer insulating layer 221. The multiple first inductor wirings 11 are disposed parallel to each other along the X direction. The second end portion 11b of the first inductor wiring 11 that is positioned furthermost towards the positive X direction side is electrically connected to the low-resistance portion 211 via a second connection wiring 52. The coil 10 is thus electrically connected to the low-resistance portion 211. The second connection wiring 52 is a via wiring provided in the opening 221a in the first-layer insulating layer 221 and penetrates through the first-layer insulating layer 221.

The conductive material of the first inductor wirings 11 is preferably, for example, Au, Ag, Ni, Cu, Al or an alloy or compound containing any of these materials. The conductive material of the first inductor wirings 11 is more preferably Cu, which has low conductivity. The first inductor wirings 11 may have a multilayer structure including a seed layer and an electrolytic plating layer, and may include Ti or Ni as the seed layer.

The second inductor wiring 12 extends along the main surface 21f. The first inductor wirings 11 and the second inductor wiring 12 are disposed side by side in a direction perpendicular to the main surface 21f (Z direction). Specifically, the second inductor wiring 12 is disposed nearer to the positive Z direction side than the first inductor wirings 11. The second inductor wiring 12 is electrically connected to the first inductor wirings 11. The second inductor wiring 12 includes multiple body wiring portions 121 and a pad portion 122. The conductive material of the second inductor wiring 12 is preferably the same as that of the first inductor wirings 11.

Each body wiring portion 121 extends in a straight line from a first end 121a to a second end 121b in the negative Y direction with a slight tilt towards the X direction. Multiple body wiring portions 121 are disposed in parallel along the X direction. The pad portion 122 extends in a straight line in the Y direction. The pad portion 122 is formed so as to be wider than the body wiring portions 121. The pad portion 122 is connected to the second end portion 121b of the body wiring portion 121 positioned furthermost towards the negative X direction side. The first end portion 121a of the body wiring portion 121 is connected to the first end portion 11a of the first inductor wiring 11 via the first connection wiring 51. The first connection wiring 51 is a via wiring provided inside the second-layer insulating layer 222. The second end portion 121b of the body wiring portion 121 is connected to the second end portion 11b of the first inductor wiring 11 via the first connection wiring 51. With this configuration, the first inductor wirings 11, the first connection wirings 51, and the body wiring portions 121 are connected to each other in this order to form the coil 10 in a spiral helical shape. The coil 10 may be spiral helical shape, a meandering shape, or a linear shape. Furthermore, the coil 10 may have a shape that is a combination of these shapes.

In this embodiment, an axial direction CA of the coil 10 is parallel to the main surface 21f of the semiconductor substrate 21. The axial direction of the coil refers to a direction extending along a winding axis of a helix around which the coil is wound. This reduces the proportion of the magnetic flux generated by the coil 10 that passes through the semiconductor substrate 21, more specifically, the low-resistance portion 211, which contains a semiconductor material. Therefore, even if the electronic component 1 includes a semiconductor substrate 21 that contains a semiconductor material and the low-resistance portion 211, the loss due to eddy currents can be reduced. In particular, even when a radio-frequency signal flows through the coil 10, a fall in the Q value of the coil 10 is reduced, and thus, an appropriate configuration for a radio-frequency inductor can be realized. The second inductor wiring 12 may have a multilayer structure including a seed layer and an electrolytic plating layer, and may include Ti or Ni as the seed layer.

The first external terminal 41 is composed of a conductive material and, for example, has a two-layer structure consisting of Ni and Au stacked in this order. The configuration of the first external terminal 41 is not particularly limited, and for example, may be a three-layer structure consisting of Cu, Ni, and Au stacked in this order, may include a Pd layer as a barrier layer as needed, and may have Sn plated on the outer surface. Furthermore, the outer surface of the first external terminal 41 may be protected by a solder resist.

The first external terminal 41 is electrically connected to the pad portion 122 of the second inductor wiring 12 via third connection wirings 53. The third connection wirings 53 are via wirings provided in the openings 222a in the second-layer insulating layer 222. The shape of the first external terminal 41 is not particularly limited, but is a rectangular shape when viewed in the Z direction in this embodiment. Viewed in the Z direction, the first external terminal 41 is disposed towards the negative X direction side from the center of the semiconductor substrate 21. In this embodiment, the first external terminal 41 is electrically connected to the coil 10 and is located along a plane parallel to the main surface 21f. This allows the electronic component 1 to be easily mounted on motherboard boards, package boards, and so on.

The first dummy external terminal 61 is preferably composed of the same conductive material as the first external terminal 41. The first dummy external terminal 61 is electrically isolated. In other words, the first dummy external terminal 61 is not electrically connected to the coil 10. The shape of the first dummy external terminal 61 is not particularly limited, but is a rectangular shape when viewed in the Z direction in this embodiment. Viewed in the Z direction, the first dummy external terminal 61 is disposed towards the positive X direction side from the center of the semiconductor substrate 21. By providing the first dummy external terminal 61, not only the first external terminal 41 but also the first dummy external terminal 61 can be fixed to a motherboard or the like via solder or the like when the electronic component 1 is mounted on a motherboard and so on. Therefore, the posture of the electronic component 1 is stable, and the electronic component 1 can be easily fixed to a motherboard or the like.

The second external terminal 42 is preferably composed of conductive material, for example, Al, Cu, Ni, Ti, or Au, or a combination of any of these metals. Silicidation may be performed by forming a Ni layer using a sputtering method and then performing a heat treatment. This enables the electrical resistance of the second external terminal 42 to be further lowered. The second external terminal 42 is preferably composed of a metal. The second external terminal 42 preferably has a lower electrical resistivity than the low-resistance portion 211.

The shape and arrangement of the second external terminal 42 are not particularly limited. In this embodiment, the second external terminal 42 is provided over the entire lower surface of the semiconductor substrate 21. The second external terminal 42 is provided along a plane parallel to the main surface 21f. This allows the electronic component 1 to be easily mounted on motherboard boards, package boards, and so on. The second external terminal 42 is connected to the low-resistance portion 211. Providing the second external terminal 42 allows the low-resistance portion 211 and the second external terminal 42 to be used together as an external terminal of the coil 10. Therefore, the electrical resistance of the external terminal of the coil 10 can be reduced compared to a case where the second external terminal 42 is not provided. The second external terminal 42 is not an essential component and does not need to be provided on the electronic component 1. For example, if the second external terminal 42 is not provided, the first dummy external terminal 61 may be electrically connected to the coil 10 and used as a second external terminal.

According to the electronic component 1, since the axial direction CA of the coil 10 is parallel to the main surface 21f, the proportion of the magnetic flux generated by the coil 10 that passes through the semiconductor substrate 21 can be reduced. Therefore, even if the electronic component 1 includes the semiconductor substrate 21 containing a semiconductor material and the low-resistance portion 211, loss due to eddy currents can be reduced. An example of the size of the electronic component 1 is 0.4 mm (length)×0.2 mm (width)×95 μm (thickness).

The insulating layer 22 is preferably positioned inside the outer edge of the semiconductor substrate 21 when viewed in a direction perpendicular to the main surface 21f With this configuration, it is possible to suppress a situation in which the insulating layer 22 comes into contact with a cutting blade when individual electronic components 1 are being formed via cutting, thereby helping prevent resin from clogging the cutting blade. Therefore, individual electronic components 1 can be easily made.

The electronic component 1 preferably further includes an organic insulating layer composed of an organic insulating material and an inorganic insulating layer composed of an inorganic insulating material. Specifically in this embodiment, the first-layer insulating layer 221 is an inorganic insulating layer and the second-layer insulating layer 222 is an organic insulating layer. This configuration improves the degree of freedom when designing the electronic component 1 because the electronic component 1 includes an organic insulating layer and an inorganic insulating layer.

Preferably, the low-resistance portion 211 is exposed from at least part of the outer surface of the semiconductor substrate 21, and the second external terminal 42 is provided on the part of the outer surface where the low-resistance portion 211 is exposed and is connected to the low-resistance portion 211. With this configuration, the low-resistance portion 211 and the second external terminal 42 can be used together as an external terminal of the coil 10. Therefore, the electrical resistance of the external terminal of the coil 10 can be reduced compared to a case where the second external terminal 42 is not provided.

The coil 10 preferably includes the first inductor wirings 11 extending along the main surface 21f and the second inductor wiring 12 extending along the main surface 21f and electrically connected to the first inductor wirings 11. The first inductor wirings 11 and the second inductor wiring 12 are preferably disposed side by side in a direction perpendicular to the main surface 21f. The distance in a direction perpendicular to the main surface 21f between the first inductor wirings 11 and the second inductor wiring 12 is preferably smaller than the thickness of the first inductor wirings 11 in the direction perpendicular to the main surface 21f Specifically, as illustrated in FIG. 2B, a distance L1 in a direction perpendicular to the main surface 21f (Z direction) between the first inductor wirings 11 and second inductor wiring 12 is preferably smaller than a thickness t1 of the first inductor wirings 11 in the direction perpendicular to the main surface 21f. With this configuration, the thickness of the electronic component 1 in the direction perpendicular to the main surface can be reduced, thereby reducing the size of the electronic component 1.

Manufacturing Method

Next, a method of manufacturing the electronic component 1 will be described while referring to FIGS. 3A to 3K. FIGS. 3A to 3E correspond to a sectional view taken along line A-A in FIG. 1 (FIG. 2A) and FIGS. 3F to 3K correspond to a sectional view taken along line B-B in FIG. 1 (FIG. 2B).

As illustrated in FIG. 3A, a semiconductor substrate 21a that includes the low-resistance portion 211 in at least part thereof is prepared. In this embodiment, the entirety of the semiconductor substrate 21a is constituted by the low-resistance portion 211. Hereafter, in order to simplify the description, the semiconductor substrate 21A is described as being a silicon substrate. As an example of a method of forming the low-resistance portion 211, for example, the silicon substrate is doped with an impurity such as phosphine (PH₃). In this way, a doped layer is formed in the silicon substrate and this doped layer becomes the low-resistance portion 211.

As illustrated in FIG. 3B, the semiconductor substrate 21a is thermally oxidized to form the first-layer insulating layer 221, which is a thermally oxidized silicon layer, on the main surface 21f Instead of the thermally oxidized silicon layer, an organic insulating film or a combination of an organic insulating film and an inorganic insulating film may be formed on the main surface 21f and serve as the first-layer insulating layer 221. Next, the opening 221a is formed at a prescribed position in the first-layer insulating layer 221 using a photolithography method, so that part of the upper surface of the semiconductor substrate 21a is exposed. The prescribed position is the position where the second connection wiring 52 is to be provided. The etching in the photolithography method can be performed using dry etching or wet etching.

As illustrated in FIG. 3C, a seed layer, which is not illustrated, is formed on the first-layer insulating layer 221 and inside the opening 221a. After that, a resist is applied and a prescribed pattern is formed in the resist using a photolithography method. The prescribed pattern is a pattern corresponding to the shape of the first inductor wirings 11. While supplying power to the seed layer, the second connection wiring 52 and the first inductor wirings 11 are formed simultaneously using an electrolytic plating method. The DFR is then peeled off and the seed layer is etched.

As illustrated in FIG. 3D, a first-layer insulating layer 2221 is applied onto the first-layer insulating layer 221 and the first inductor wiring. Next, openings 2221a are formed at prescribed positions in the first-layer insulating layer 2221 using a photolithography method, so that parts of the upper surfaces of the first inductor wirings 11 are exposed. The prescribed positions are the positions where the first connection wirings 51 are to be provided. Then, if necessary, the first-layer insulating layer 2221 is dried and cured. Instead of the photolithography method, a laser may be used to form the openings 2221a.

As illustrated in FIG. 3E, a seed layer, which is not illustrated, is formed on the first-layer insulating layer 2221 and inside the openings 2221a. After that, a resist is applied and a prescribed pattern is formed in the resist using a photolithography method. The prescribed pattern is a pattern corresponding to the shape of the second inductor wiring 12. While supplying power to the seed layer, the first connection wirings 51 and the second inductor wiring 12 (body wiring portions 121 and pad portion 122) are simultaneously formed using an electrolytic plating method. The DFR is then peeled off and the seed layer is etched. Thus, the coil 10 including the first inductor wirings 11 and the second inductor wiring 12 is formed.

As illustrated in FIG. 3F, a second-layer insulating layer 2222 is applied onto the first-layer insulating layer 2221 so as to cover the second inductor wiring 12. As a result, the first-layer insulating layer 2221 and the second-layer insulating layer 2222 are stacked to form the second-layer insulating layer 222. Next, the openings 222a are formed at prescribed positions in the second insulating layer 222 using a photolithography method, so that parts of the upper surface of the pad portion 122 of the second inductor wiring 12 are exposed. The prescribed positions are the positions where the third connection wirings 53 are to be provided. Next, if necessary, the second-layer insulating layer 2222 is dried and cured. Instead of the photolithography method, a laser may be used to form the openings 222a.

As illustrated in FIG. 3G, the first external terminal 41 is formed so to cover a portion of the upper surface of the pad portion 122 of the second inductor wiring 12, which is exposed from the second-layer insulating layer 222. At the same time as the formation of the first external terminal 41, the first dummy external terminal 61 is formed on the second-layer insulating layer 222. An example of a method for forming the first external terminal 41 and the first dummy external terminal 61 is, for example, a method in which a base Cu layer is formed using an electrolytic plating method, and then a Ni plating layer and an Au plating layer are formed in this order using an electroless plating method.

As illustrated in FIG. 3H, the lower surface of the semiconductor substrate 21a is ground down. Thus, the semiconductor substrate 21, whose thickness has been adjusted, is formed. The grinding may be performed using chemical dry or wet etching methods, using mechanical grinding or polishing, or using chemical and mechanical methods such as CMP. The semiconductor substrate may be ground down at the same time as molded resin after mounting the electronic component without performing grinding in this step.

As illustrated in FIG. 3I, the second external terminal 42 is formed on the lower surface of the semiconductor substrate 21 using a sputtering or plating method. The conductive material of the second external terminal 42 is Cu, for example.

The electronic component 1, as illustrated in FIG. 3K, is manufactured by cutting the electronic component into individual pieces along the cutting lines D, as illustrated in FIG. 3J.

The method of manufacturing the electronic component 1 described above includes a step of forming the low-resistance portion 211 in the semiconductor substrate 21a and a step of forming the coil 10 after forming the low-resistance portion 211. With this configuration, the step of forming the low-resistance portion 211, which has a high heat load, is performed before the step of forming the coil 10, and therefore the coil 10 is not subjected to an unnecessary heat load. This enables an electronic component 1 that can improve quality to be manufactured. In addition, when forming the coil 10, heat-sensitive organic materials and the like can be used, resulting in improved freedom of design.

### Second Embodiment

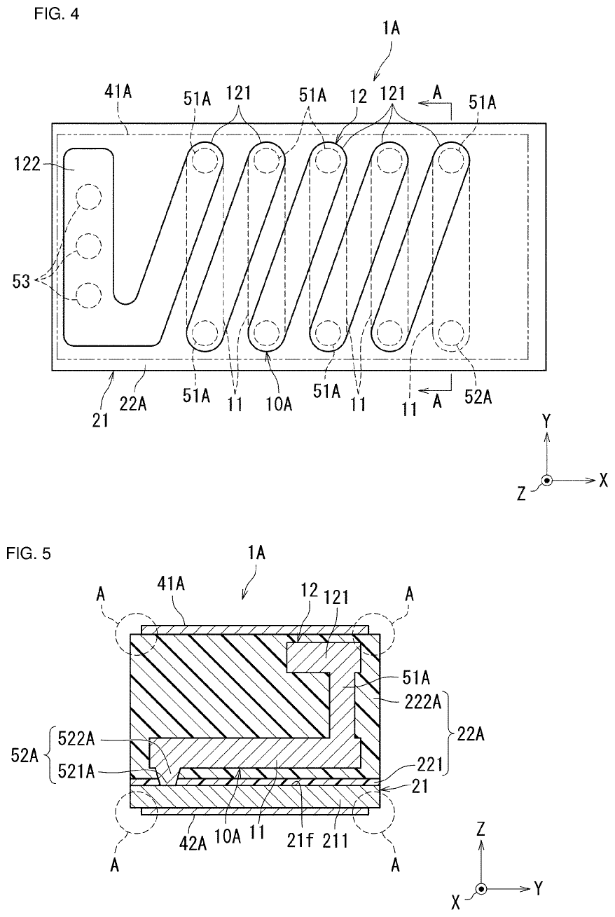

FIG. 4 is a plan view illustrating an electronic component according to a Second Embodiment. FIG. 5 is a sectional view taken along line A-A in FIG. 4. FIG. 4 is a plan view corresponding to FIG. 1. The Second Embodiment differs from the First Embodiment with respect to the shape of each of the first external terminal, the second external terminal, the first connection wirings, and the second connection wiring, and with respect to the thickness of the insulating layer. These differences will be described below. The rest of the configuration is the same as that of the First Embodiment, and parts that are the same as in the First Embodiment are denoted by the same symbols and description thereof is omitted.

As illustrated in FIGS. 4 and 5 (in particular, see symbols A), a first external terminal 41A and a second external terminal 42A are positioned inside the outer edge of the main surface 21f of the semiconductor substrate 21 when viewed in a direction perpendicular to the main surface 21f (Z direction). This helps prevent the cutting blade from contacting the first external terminal 41A and the second external terminal 42A when individual electronic components 1A are being formed via cutting, and thus helps prevent deformation and burring of the first external terminal 41A and the second external terminal 42A.

In this embodiment, first connection wirings 51A are vertical wirings extending in a direction perpendicular to the main surface 21f. The length of the first connection wirings 51A in the extension direction (Z direction) is longer than the length of the first connection wirings 51 of the First Embodiment in the extension direction (Z direction).

Here, increasing the length of the first connection wirings 51A in the extension direction allows the volume of an inner magnetic path (core portion) of a coil 10A to be increased, and this results in an increase in the Q value of the coil 10A. However, increasing the length of the first connection wirings 51A in the extension direction also increases the electrical resistance of the coil 10A. In this embodiment, since the first connection wirings 51A are vertical wirings, the first connection wirings 51A can connect the first inductor wirings 11 and the second inductor wiring 12 to each other at the shortest distance. Therefore, even when the length of the first connection wirings 51A in the extension direction is increased, the volume of the inner magnetic path of the coil 10A can be increased while suppressing an increase in the electrical resistance of the coil 10A. As a result, the Q value of the coil 10A can be increased. The first connection wirings 51A correspond to a “connection wiring” in the claims.

The thickness of a second-layer insulating layer 222A is greater than the thickness of the second-layer insulating layer 222 in the First Embodiment. A second connection wiring 52A includes a first-layer via wiring 521A that penetrates through the first-layer insulating layer 221 and a second-layer via wiring 522A that is provided in the second-layer insulating layer 222A and on the first-layer via wiring 521A. The upper surface of the second-layer via wiring 522A is connected to the lower surface of the corresponding first inductor wiring 11. As a result, the second connection wiring 52A electrically connects the first inductor wiring 11 to the low-resistance portion 211. In this embodiment, since the second-layer via wiring 522A is provided, the first inductor wiring 11 is not in contact with the first-layer insulating layer 221 and is disposed a prescribed distance away from the first-layer insulating layer 221 in the positive Z direction. This ensures more reliable insulation between the coil 10A and the low-resistance portion 211.

### Third Embodiment

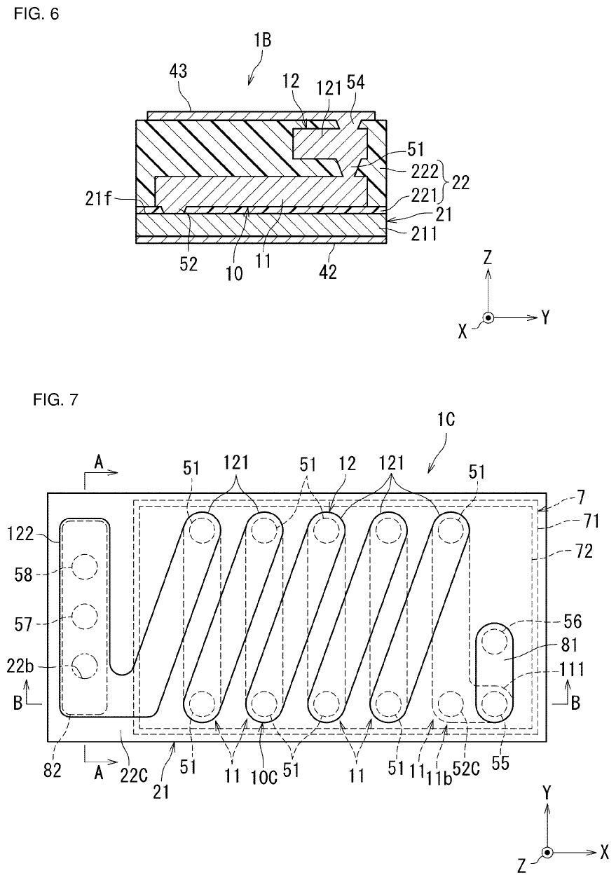

FIG. 6 is a sectional view illustrating an electronic component according to a Third Embodiment. FIG. 6 is a sectional view corresponding to FIG. 2A. The Third Embodiment differs from the First Embodiment in that a third external terminal is provided. This difference will be described below. The rest of the configuration is the same as that of the First Embodiment, and parts that are the same as in the First Embodiment are denoted by the same symbols and description thereof is omitted.

As illustrated in FIG. 6, a third external terminal 43 is provided on the second-layer insulating layer 222 instead of the first dummy external terminal 61 of the First Embodiment. The third external terminal 43 is electrically connected to the body wiring portion 121 that is located furthermost towards the positive X direction side via a fourth connection wiring 54. The fourth connection wiring 54 is a via wiring provided inside the second-layer insulating layer 222. Thus, an electronic component 1B having three terminals (first to third external terminals 41 to 43) can be obtained. When the electronic component 1B is used, for example, the semiconductor substrate 21 on which the second external terminal 42 is provided can be grounded (GND).

The thickness of the first-layer insulating layer 221 is relatively small. In other words, the gap between the semiconductor substrate 21 and the first inductor wirings 11 is small. Therefore, a capacitor may be formed by the semiconductor substrate 21, the first inductor wirings 11, and the first-layer insulating layer 221. In this case, the electronic component 1B can perform resonance control.

### Fourth Embodiment

Configuration

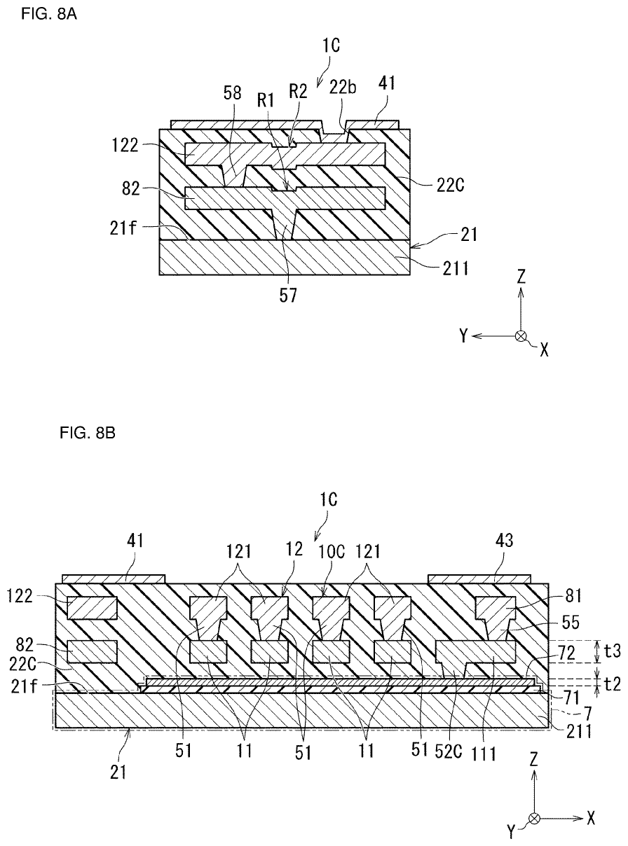

FIG. 7 is a sectional view illustrating an electronic component according to a Fourth Embodiment. FIG. 8A is a sectional view taken along line A-A in FIG. 7. FIG. 8B is a sectional view taken along line B-B in FIG. 7. FIG. 7 is a plan view corresponding to FIG. 1. The Fourth Embodiment mainly differs from the First Embodiment in that a capacitor element is provided. This difference will be described below. The rest of the configuration is the same as that of the First Embodiment, and parts that are the same as in the First Embodiment are denoted by the same symbols and description thereof is omitted. For convenience, the first external terminal and the third external terminal described below are omitted from FIG. 7.

As illustrated in FIG. 7 and FIG. 8A and FIG. 8B, the low-resistance portion 211 is exposed from at least part of the main surface 21f. In this embodiment, the low-resistance portion 211 is exposed from the entirety of the main surface 21f. An electronic component 1C further includes a dielectric portion 71 provided on the low-resistance portion 211 and an electrode portion 72 provided on the dielectric portion 71. A capacitor element 7 is formed by the low-resistance portion 211, the dielectric portion 71, and the electrode portion 72.

The dielectric portion 71 is preferably formed of an inorganic insulating material such as, for example, a silicon oxide film, a silicon nitride film, or a silicon oxynitride film. When the semiconductor substrate 21 is a silicon substrate, for example, the dielectric portion 71 is preferably thermally oxidized silicon, which is formed by thermally oxidizing the semiconductor substrate 21. The thickness of the dielectric portion 71 is not particularly limited, but is around 0.1 μm, for example. The electrode portion 72 is preferably formed of a metallic material such as Ti or Cu, for example. The thickness of the electrode portion 72 is not particularly limited, but is around 2 μm, for example.

In this embodiment, an insulating layer 22C is provided on the main surface 21f of the semiconductor substrate 21 so as to cover a coil 10C and the capacitor element 7. An opening 22b is provided in the insulating layer 22C so that part of the upper surface of the pad portion 122 of the second inductor wiring 12 is exposed. The insulating layer 22C is preferably formed of the same material as the second-layer insulating layer 222 described in the First Embodiment. The thickness of the insulating layer 22C is not particularly limited, but is around 10 μm, for example.

Instead of the first dummy external terminal 61 described in the First Embodiment, the third external terminal 43 is provided on the insulating layer 22C. The third external terminal 43 is preferably formed of the same material as the first external terminal 41. A pad portion 111 extending from the second end portion 11b towards the positive X direction side is provided at the second end portion 11b of the first inductor wiring 11 that is positioned furthermost towards the positive X direction side.

A first relay wiring 81 and a second relay wiring 82 are provided in the insulating layer 22C. The first relay wiring 81 is disposed towards the positive Z direction side from the pad portion 111 of the corresponding first inductor wiring 11, and is provided in the same layer as the second inductor wiring 12. The second relay wiring 82 is disposed towards the negative Z direction side from the pad portion 122 of the second inductor wiring 12, and is provided in the same layer as the first inductor wirings 11. The first relay wiring 81 is electrically connected to the third external terminal 43 via a sixth connection wiring 56. The first relay wiring 81 is electrically connected to the pad portion 111 of the first inductor wiring 11 via a fifth connection wiring 55.

The second end portion 11b of the first inductor wiring 11 that is positioned furthermost towards the positive X direction side is electrically connected to the electrode portion 72 via a second connection wiring 52C. The first external terminal 41 covers the upper surface of the pad portion 122 exposed through the opening 22b. As a result, the first external terminal 41 is connected to the pad portion 122. The second relay wiring 82 is electrically connected to the pad portion 122 of the second inductor wiring 12 via an eighth connection wiring 58. The second relay wiring 82 is electrically connected to the low-resistance portion 211 of the semiconductor substrate 21 via a seventh connection wiring 57. With the above configuration, the coil 10C and the capacitor element 7 are connected in parallel with each other.

A first recess R1 is provided in the upper surface of the second relay wiring 82 at a position corresponding to the seventh connection wiring 57. A second recess R2 is provided in the upper surface of the pad portion 122 of the second inductor wiring 12 at a position corresponding to the seventh connection wiring 57. The first recess R1 and second recess R2 create an anchor effect, and this improves the adhesion between the second relay wiring 82 and second inductor wiring 12 (i.e., the coil 10C) and the insulating layer 22C.

According to this embodiment, since the capacitor element 7 is additionally provided, a composite electronic component such as an LC filter can be obtained. An example of the size of the electronic component 1C is 0.4 mm (length)×0.2 mm (width)×90 μm (thickness).

The coil 10C preferably includes the first inductor wirings 11 extending along the main surface 21f and the second inductor wiring 12 extending along the main surface 21f and electrically connected to the first inductor wirings 11. The first inductor wirings 11 and the second inductor wiring 12 are preferably disposed side by side in a direction perpendicular to the main surface 21f. A thickness t2 of the electrode portion 72 in a direction perpendicular to the main surface 21f is preferably smaller than a thickness t3 of the first inductor wirings 11 in a direction perpendicular to the main surface 21f.

Here, the capacitor element, unlike the coil, is a voltage element and therefore does not carry a DC current. Therefore, in the above configuration, the thickness of the electrode portion 72 is intentionally made small. This enables a small-sized electronic component 1C to be obtained even when the capacitor element 7 is additionally provided.

Manufacturing Method

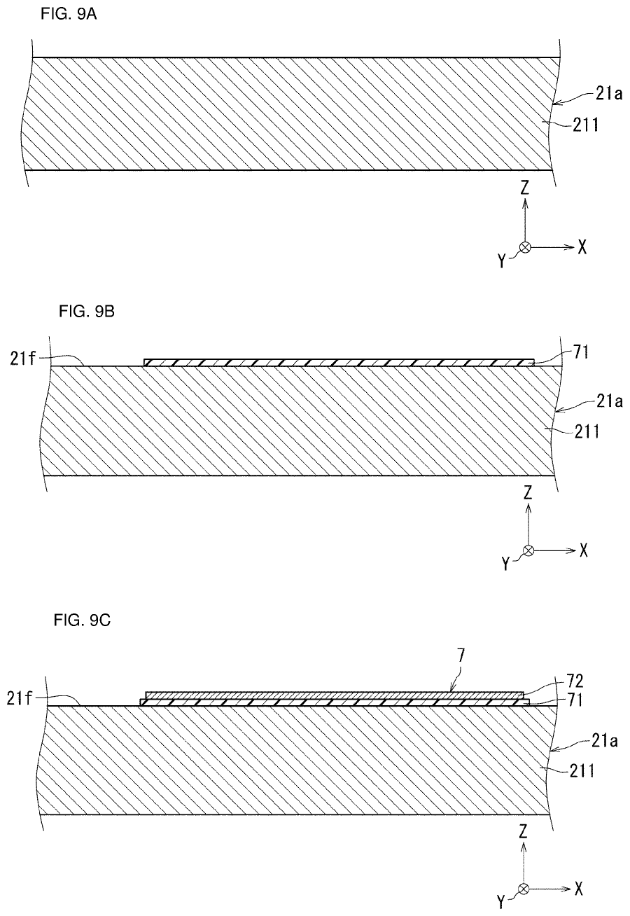

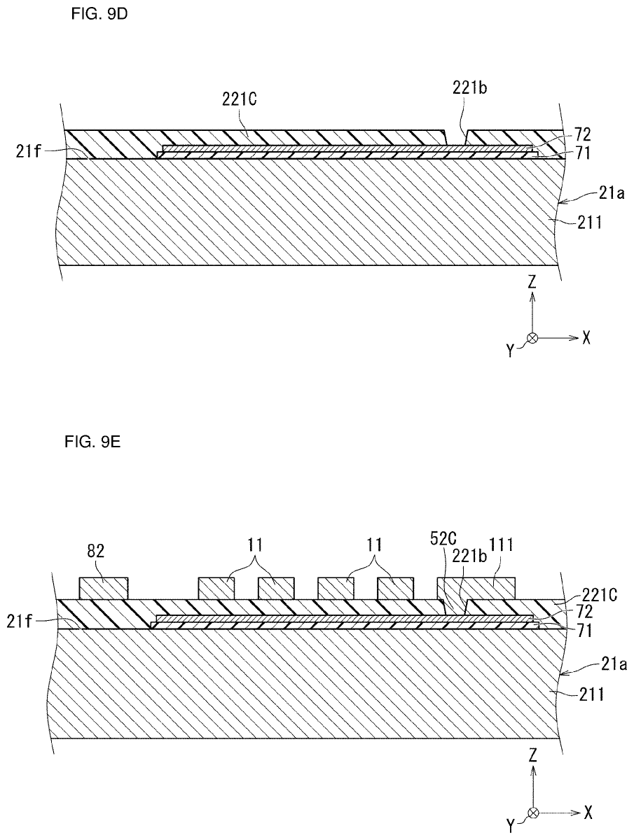

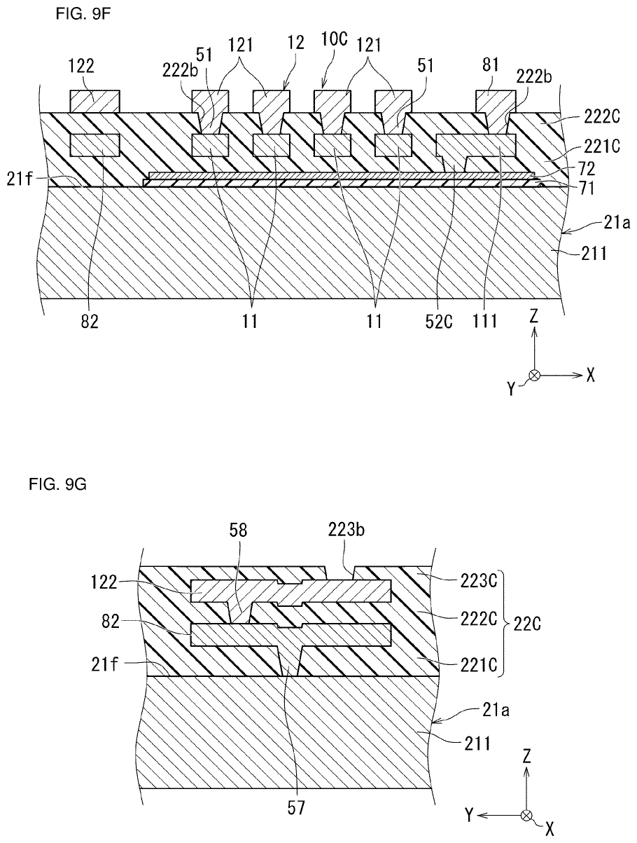

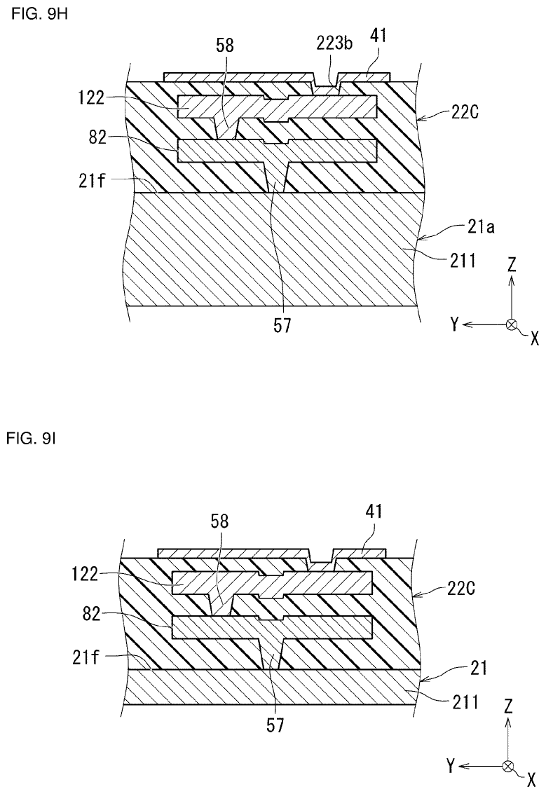

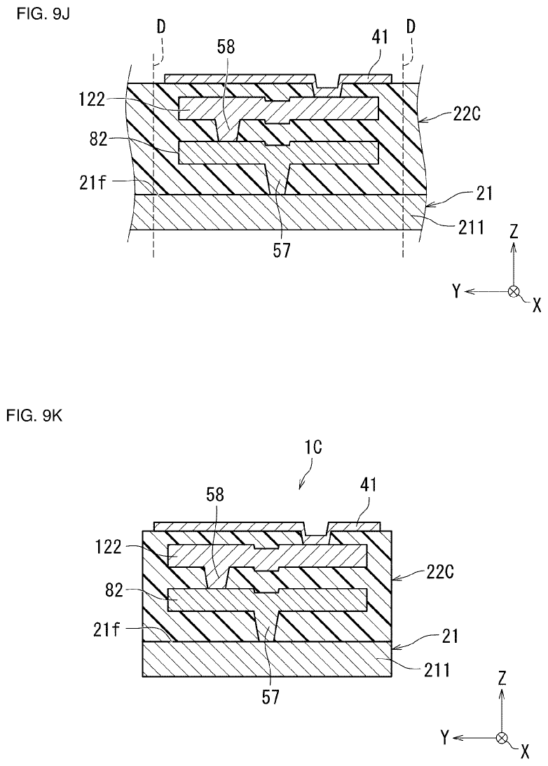

Next, a method of manufacturing the electronic component 1C will be described while referring to FIGS. 9A to 9K. FIGS. 9A to 9F correspond to a sectional view taken along line B-B in FIG. 7 (FIG. 8B) and FIGS. 9G to 9K correspond to a sectional view taken along line A-A in FIG. 7 (FIG. 8A).

As illustrated in FIG. 9A, the semiconductor substrate 21a that includes the low-resistance portion 211 in at least part thereof is prepared. In this embodiment, the entirety of the semiconductor substrate 21a is constituted by the low-resistance portion 211. Hereafter, in order to simplify the description, the semiconductor substrate 21A is described as being a silicon substrate. The method of forming the low-resistance portion 211 may be substantially the same as that in the First Embodiment.

As illustrated in FIG. 9B, the semiconductor substrate 21a is thermally oxidized to form a thermally oxidized silicon layer on the main surface 21f. Instead of the thermally oxidized silicon layer, an organic insulating film or a combination of an organic insulating film and an inorganic insulating film may be formed on the main surface 21f. Next, using a photolithography method, the dielectric portion 71 is formed so that a portion of the upper surface of the semiconductor substrate 21a is exposed. The etching in the photolithography method can be performed using dry etching or wet etching.

As illustrated in FIG. 9C, a metal film such as a Ti, Cu, or Al film is formed on the exposed part of the main surface 21f and on the dielectric portion 71 by sputtering, for example. Next, the electrode portion 72 is formed on the dielectric portion 71 by etching the metal film on the exposed part of the main surface 21f using a photolithography method. In this way, the capacitor element 7 that includes the low-resistance portion 211, the dielectric portion 71, and the electrode portion 72 is formed.

As illustrated in FIG. 9D, a first-layer insulating layer 221C is applied onto the exposed part of the main surface 21f and onto the electrode portion 72. Then, using a photolithography method, an opening 221b is formed at a prescribed position in the first-layer insulating layer 221C so that part of the upper surface of the electrode portion 72 is exposed. The prescribed position is a position where the second connection wiring 52C and the seventh connection wiring 57 are to be provided. Then, if necessary, the first-layer insulating layer 221C is dried and cured. Instead of the photolithography method, a laser may be used to form the opening 221b.

As illustrated in FIG. 9E, a seed layer, which is not illustrated, is formed on the first-layer insulating layer 221C and inside the opening 221b. After that, a resist is applied and a prescribed pattern is formed in the resist using a photolithography method. The prescribed pattern is a pattern corresponding to the shapes of the first inductor wirings 11 and the second relay wiring 82. While supplying power to the seed layer, the first inductor wirings 11, the second relay wiring 82, the second connection wiring 52C, and the seventh connection wiring 57, which is not illustrated, are formed simultaneously using an electrolytic plating method. The DFR is then peeled off and the seed layer is etched.

As illustrated in FIG. 9F, a second-layer insulating layer 222C is applied onto the first-layer insulating layer 221C. Next, a plurality of openings 222b are formed at prescribed positions in the second-layer insulating layer 222C using a photolithography method so that parts of the upper surfaces of the first inductor wirings 11 and the pad portion 111 are exposed. The prescribed positions are the position where the first connection wirings 51, the fifth connection wiring 55, and the eighth connection wiring 58 are to be provided. Then, if necessary, the second-layer insulating layer 222C is dried and cured. Instead of the photolithography method, a laser may be used to form the openings 222b. Next, a seed layer, which is not illustrated, is formed on the second-layer insulating layer 222C and inside the openings 222b. After that, a resist is applied and a prescribed pattern is formed in the resist using a photolithography method. The prescribed pattern is a pattern corresponding to the shapes of the second inductor wiring 12 and the first relay wiring 81. While supplying power to the seed layer, the second inductor wiring 12, the first relay wiring 81, the first connection wirings 51, the fifth connection wiring 55, and the eighth connection wiring 58, which is not illustrated, are formed simultaneously using an electrolytic plating method. The DFR is then peeled off and the seed layer is etched. Thus, the coil 10C including the first inductor wirings 11 and the second inductor wiring 12 is formed.

As illustrated in FIG. 9G, a third-layer insulating layer 223C is applied onto the second-layer insulating layer 222C. As a result, the first-layer to third-layer insulating layers 221C to 223C are stacked to form an insulating layer 23C. Next, openings 223b are formed at prescribed positions in the third-layer insulating layer 223C using a photolithography method so that part of the upper surface of the pad portion 122 of the second inductor wiring 12 is exposed. The prescribed positions are a position corresponding to a connection portion between the first external terminal 41 and the pad portion 122, and a position corresponding to the connection portion between the third external terminal 43 and the first relay wiring 81. Then, if necessary, the third-layer insulating layer 223C is dried and cured. Instead of the photolithography method, a laser may be used to form the openings 223b.

As illustrated in FIG. 9H, the first external terminal 41 is formed so as to cover part of the upper surface of the pad portion 122 exposed from the insulating layer 22C. The third external terminal 43 is formed so as to cover part of the upper surface of the first relay wiring 81, which is not illustrated, that is exposed from the insulating layer 22C. An example of a method of forming the first external terminal 41 and the third external terminal 43 is, for example, a method in which a Ni plating layer and an Au plating layer are formed in this order using an electroless plating method.

As illustrated in FIG. 9I, the lower surface of the semiconductor substrate 21a is ground down. Thus, the semiconductor substrate 21, whose thickness has been adjusted, is formed. The grinding may be performed using chemical dry or wet etching methods, using mechanical grinding or polishing, or using chemical and mechanical methods such as CMP. The semiconductor substrate may be ground down at the same time as molded resin after mounting the electronic component without performing grinding in this step.

The electronic component 1C, as illustrated in FIG. 9K, is manufactured by cutting the electronic component into individual pieces along the cutting lines D, as illustrated in FIG. 9J.

The above-described method of manufacturing the electronic component 1C further includes a step of forming the capacitor element 7 between the step of forming the low-resistance portion 211 and the step of forming the coil 10C. In the step of forming the low-resistance portion 211, the low-resistance portion 211 is exposed from at least part of the main surface 21f. In the step of forming the capacitor element 7, the dielectric portion 71 is formed on the low-resistance portion 211 and the electrode portion 72 is formed on the dielectric portion 71.

With this configuration, the step of forming the low-resistance portion 211, which has a high heat load, is performed before the step of forming the coil 10C, and therefore, the coil 10C is not subjected to an unnecessary heat load. This enables an electronic component 1C that can improve quality to be manufactured.

### Fifth Embodiment

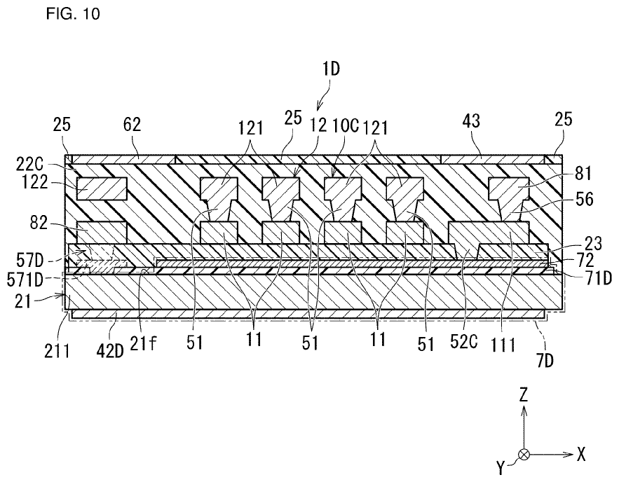

FIG. 10 is a sectional view illustrating an electronic component according to a Fifth Embodiment. FIG. 10 is a sectional view corresponding to FIG. 8B. The Fifth Embodiment differs from the Fourth Embodiment mainly in that a coating layer, an inorganic insulating layer, and a second dummy external terminal are provided. These differences will be described below. The rest of the configuration is the same as that of the Fourth Embodiment, and parts that are the same as in the Fourth Embodiment are denoted by the same symbols and description thereof is omitted.

As illustrated in FIG. 10, in this Embodiment, a second dummy external terminal 62 is provided on the upper surface of the insulating layer 22C instead of the first external terminal 41 described in the Fourth Embodiment. The second dummy external terminal 62 preferably consists of the same conductive material as the third external terminal 43. The second dummy external terminal 62 is electrically isolated. In other words, the second dummy external terminal 62 is not electrically connected to the coil 10C. By providing the second dummy external terminal 62, not only the third external terminal 43 but also the second dummy external terminal 62 can be fixed to a motherboard or the like via solder or the like when an electronic component 1D is mounted on a motherboard and so on. Therefore, the posture of the electronic component 1D is stable, and the electronic component 1D can be easily fixed to a motherboard or the like.

A coating layer 25 is provided on the upper surface of the insulating layer 22C in a region where the second dummy external terminal 62 and the third external terminal 43 are not provided. The coating layer 25 is, for example, a solder resist having epoxy resin as a main component. Providing the coating layer 25 protects the electronic component 1D from the external environment.

In this embodiment, a seventh connection wiring 57D, which connects the second relay wiring 82 to the low-resistance portion 211, includes a pad wiring 571D in a part where the seventh connection wiring 57D is connected to the low-resistance portion 211. The seventh connection wiring 57D does not appear in the cross section illustrated in FIG. 10, but is indicated by a dashed hatching line for convenience. The pad wiring 571D is preferably formed of the same conductive material as the electrode portion 72. This simplifies the process of manufacturing the seventh connection wiring 57D and therefore makes the seventh connection wiring 57D easier to manufacture. A second external terminal 42D is provided on the lower surface of the semiconductor substrate 21. The second external terminal 42D is preferably formed of the same conductive material as the second external terminal 42 described in the First Embodiment. In this embodiment, a capacitor element 7D is formed by the low-resistance portion 211 of the semiconductor substrate 21, the second external terminal 42D, a dielectric portion 71D, and the electrode portion 72.

The insulating layer 22C includes an inorganic insulating layer 23. The inorganic insulating layer 23 is present at least between the first inductor wirings 11 and the electrode portion 72, and covers the dielectric portion 71D and the electrode portion 72. The inorganic insulating layer 23 is preferably formed of, for example, a silicon oxide film, a silicon nitride film, or a silicon oxynitride film. Providing the inorganic insulating layer 23 improves the insulation between the coil 10C and the capacitor element 7D.

### Sixth Embodiment

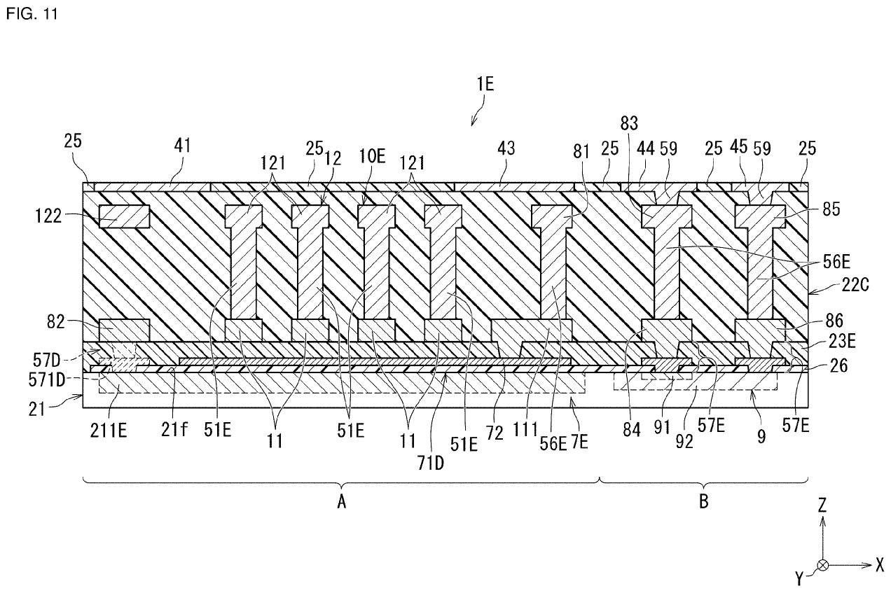

FIG. 11 is a sectional view illustrating an electronic component according to a Sixth Embodiment. FIG. 11 is a sectional view corresponding to FIG. 10. The sixth embodiment mainly differs from the fifth embodiment in that a diode element is provided and with respect to the lengths of connection wirings in the extension direction. These differences will be described below. The rest of the configuration is the same as that of the Fifth Embodiment, and parts that are the same as in the Fifth Embodiment are denoted by the same symbols and description thereof is omitted.

As illustrated in FIG. 11, in an electronic component 1E, a coil 10E and a capacitor element 7E connected in parallel with each other are provided in a region A and a diode element 9 is provided in a region B. The coil 10E and the capacitor element 7E are electrically isolated from the diode element 9. The configuration of the region A corresponds to the configuration of the electronic component 1D of the Fifth Embodiment.

An interlayer insulating layer 26 is provided on the main surface 21f of the semiconductor substrate 21. The part of the interlayer insulating layer 26 that is located in the region A constitutes the dielectric portion 71D of the capacitor element 7E. An inorganic insulating layer 23E covering the capacitor element 7E is provided on the interlayer insulating layer 26.

Diode Element

A fourth external terminal 44 and a fifth external terminal 45 are provided on the insulating layer 22C in the region B. The fourth external terminal 44 and the fifth external terminal 45 are preferably formed of the same conductive material as the third external terminal 43.

A low-resistance portion 211E is provided in part of the semiconductor substrate 21. Specifically, the low-resistance portion 211E is disposed within the semiconductor substrate 21 in the region A and is provided along the main surface 21f so as to be exposed from the main surface 21f. The low-resistance portion 211E is not exposed to outside the electronic component 1E. The semiconductor substrate 21 includes the diode element 9 in a region other than where the low-resistance portion 211E is disposed. The diode element 9 includes a P-type semiconductor layer 91 and an N-type semiconductor layer 92.

The P-type semiconductor layer 91 can be formed by doping boron, for example, when the semiconductor substrate 21 is a silicon substrate. The P-type semiconductor layer 91 is provided within the semiconductor substrate 21 so as to be exposed from the main surface 21f The N-type semiconductor layer 92 can be formed by doping phosphorus, for example, when the semiconductor substrate 21 is a silicon substrate. The N-type semiconductor layer 92 is provided inside the semiconductor substrate 21 so as to cover the P-type semiconductor layer 91 while contacting the P-type semiconductor layer 91. Part of the N-type semiconductor layer 92 is exposed from the main surface 21f.

The P-type semiconductor layer 91 is connected to the fourth external terminal 44 via a seventh connection wiring 57E extending in the positive Z direction from the exposed surface out of the main surface 21f and penetrating through the inorganic insulating layer 23E and the interlayer insulating layer 26, a fourth relay wiring 84 provided on the seventh connection wiring 57E, a sixth connection wiring 56E extending in the positive Z direction from the upper surface of the fourth relay wiring 84, a third relay wiring 83 provided on the upper surface of the sixth connection wiring 56E, and a ninth connection wiring 59 provided on the upper surface of the third relay wiring 83. The sixth connection wiring 56E is a vertical wiring extending in a direction perpendicular to the main surface 21f. With the above configuration, the fourth external terminal 44 is electrically connected to the P-type semiconductor layer 91.

The N-type semiconductor layer 92 is connected to the fifth external terminal 45 via the seventh connection wiring 57E extending in the positive Z direction from the exposed surface out of the main surface 21f and penetrating through the inorganic insulating layer 23E and the interlayer insulating layer 26, a sixth relay wiring 86 provided on the seventh connection wiring 57E, the sixth connection wiring 56E extending in the positive Z direction from the upper surface of the sixth relay wiring 86, a fifth relay wiring 85 provided on the upper surface of the sixth relay wiring 56E, and the ninth connection wiring 59 provided on the upper surface of the fifth relay wiring 85. With the above configuration, the fifth external terminal 45 is electrically connected to the N-type semiconductor layer 92.

Coil and Capacitor Element

Compared to the configuration of the Fifth Embodiment, in this Embodiment, the first external terminal 41 is provided instead of the second dummy external terminal 62. The first external terminal 41 is electrically connected to the pad portion 122 of the second inductor wiring 12. First connection wirings 51E are vertical wirings extending in the Z direction. This allows the volume of the inner magnetic path of the coil 10E to be increased while suppressing an increase in the electrical resistance of the coil 10E, and this results in an increase in the Q value of the coil 10E. The first connection wirings 51E correspond to a “connection wiring” in the claims.

Preferably, the fifth relay wiring 85, the sixth relay wiring 86, and the sixth connection wiring 56E are composed of the same conductive material as the coil 10E and are electrically isolated from the coil 10E. With this configuration, the fifth relay wiring 85, the sixth relay wiring 86, and the sixth connection wiring 56E can form an element that is isolated from the coil 10E. The fifth relay wiring 85, the sixth relay wiring 86, and the sixth connection wiring 56 correspond to a “wiring portion” in the claims.

The method of manufacturing the electronic component 1E preferably further includes a step of forming the diode element 9 between the step of forming the low-resistance portion 211E and the step of forming the coil 10E. In the step of forming the low-resistance portion 211E, the semiconductor substrate 21a is preferably made to include the low-resistance portion 211E in part thereof. In the step of forming the diode element 9, the diode element 9 is preferably formed in a region of the semiconductor substrate 21a other than that where the low-resistance portion 211E is disposed.

With this configuration, the step of forming the low-resistance portion 211E, which has a high heat load, is performed before the step of forming the coil 10E, and therefore the coil 10E is not subjected to an unnecessary heat load. This enables an electronic component 1E that can improve quality to be manufactured.

The present disclosure is not limited to the above-described embodiments and design changes can be made within a range that does not depart from the gist of the present disclosure. For example, the features of the first to Sixth Embodiments may be combined with each other in various ways.

In the above embodiments, the coil is a spiral helical coil, but there are no particular limits on the structure, shape, material, and so on of the coil. For example, the coil may have a planar spiral shape extending along a main surface of the semiconductor substrate.

In the above embodiments, an insulating layer and external terminals are provided on the semiconductor substrate as electronic components, but the insulating layer and external terminals are not essential components. In this case, the end portions of the coil may be directly connected to an external circuit when the coil is connected to an external circuit.

<1> An electronic component comprising: a semiconductor substrate having a main surface and containing a semiconductor material; and a coil provided on the main surface and composed of a conductive material. The semiconductor substrate includes a low-resistance portion having a lower electrical resistance than a semiconductor composed of the semiconductor material, and the coil is electrically connected to the low-resistance portion, and an axial direction of the coil is parallel to the main surface.

<2> The electronic component according to <1>, further comprising an organic insulating layer composed of an organic insulating material and an inorganic insulating layer composed of an inorganic insulating material.

<3> The electronic component according to <2>, wherein the inorganic insulating layer is located at least between the semiconductor substrate and the coil.

<4> The electronic component according to <2> or <3>, wherein the organic insulating layer is located in at least one out of between adjacent turns of the coil and in an inner diameter part of the coil.

<5> The electronic component according to any one of <1> to <4>, further comprising a first external terminal that is electrically connected to the coil and provided along a plane parallel to the main surface.

<6> The electronic component according to <5>, wherein the first external terminal is positioned inside an outer edge of the main surface when viewed in a direction perpendicular to the main surface.

<7> The electronic component according to any one of <1> to <6>, wherein the low-resistance portion is exposed from at least part of an outer surface of the semiconductor substrate, and the electronic component further comprises a second outer terminal provided on a part of the outer surface where the low-resistance portion is exposed and connected to the low-resistance portion.

<8> The electronic component according to <7>, wherein the second outer terminal is provided along a plane parallel to the main surface.

<9> The electronic component according to <7> or <8>, wherein the second external terminal is positioned inside an outer edge of the main surface when viewed in a direction perpendicular to the main surface.

<10> The electronic component according to any one of <1> to <9>, wherein the coil includes a first inductor wiring extending along the main surface and a second inductor wiring extending along the main surface and electrically connected to the first inductor wiring, the first inductor wiring and the second inductor wiring are disposed side by side in a direction perpendicular to the main surface, and a distance between the first inductor wiring and the second inductor wiring in a direction perpendicular to the main surface is less than a thickness of the first inductor wiring in a direction perpendicular to the main surface.

<11> The electronic component according to <10>, wherein the coil further includes a connection wiring that connects the first inductor wiring and the second inductor wiring to each other, and the connection wiring extends in a direction perpendicular to the main surface.

<12> The electronic component according to any one of <1> to <11>, wherein the semiconductor substrate is entirely constituted by the low-resistance portion.

<13> The electronic component according to any one of <1> to <12>, wherein the low-resistance portion is exposed from at least part of the main surface, and the electronic component further comprises a dielectric portion provided on the low-resistance portion and an electrode portion provided on the dielectric portion. Also, a capacitor element is formed by the low-resistance portion, the dielectric portion, and the electrode portion.

<14> The electronic component according to <13>, wherein the coil includes a first inductor wiring extending along the main surface and a second inductor wiring extending along the main surface and electrically connected to the first inductor wiring. Also, the first inductor wiring and the second inductor wiring are disposed side by side in a direction perpendicular to the main surface, and a thickness of the electrode portion in a direction perpendicular to the main surface is less than a thickness of the first inductor wiring in a direction perpendicular to the main surface.

<15> The electronic component according to any one of <1> to <14>, wherein part of the semiconductor substrate is constituted by the low-resistance portion, and the semiconductor substrate includes a diode element in a region other than a region where the low-resistance portion is disposed.

<16> The electronic component according to any one of <1> to <15>, further comprising a wiring portion composed of a conductive material identical to the conductive material and electrically isolated from the coil.

<17> A method of manufacturing the electronic component according to any one of <1> to <16>, comprising a step of forming the low-resistance portion in the semiconductor substrate; and a step of forming the coil after forming the low-resistance portion.

What is claimed is:

1. An electronic component comprising:
a semiconductor substrate having a main surface and containing a semiconductor material; and
a coil on the main surface and made of a conductive material,
wherein
the semiconductor substrate includes a low-resistance portion having a lower electrical resistance than a semiconductor made of the semiconductor material, and
the coil is electrically connected to the low-resistance portion, and an axial direction of the coil is parallel to the main surface.

2. The electronic component according to claim 1, further comprising:
an organic insulating layer including an organic insulating material and an inorganic insulating layer made of an inorganic insulating material.

3. The electronic component according to claim 2, wherein
the inorganic insulating layer is at least between the semiconductor substrate and the coil.

4. The electronic component according to claim 2, wherein
the organic insulating layer is at least one of between adjacent turns of the coil and in an inner diameter portion of the coil.

5. The electronic component according to claim 1, further comprising:
a first external terminal that is electrically connected to the coil and disposed along a plane parallel to the main surface.

6. The electronic component according to claim 5, wherein
the first external terminal is inside an outer edge of the main surface when viewed in a direction perpendicular to the main surface.

7. The electronic component according to claim 1, further comprising:
a second outer terminal,
wherein the low-resistance portion is exposed from at least a portion of an outer surface of the semiconductor substrate,
the second outer terminal is on the portion of the outer surface where the low-resistance portion is exposed, and
the second outer terminal is connected to the low-resistance portion.

8. The electronic component according to claim 7, wherein
the second outer terminal is disposed along a plane parallel to the main surface.

9. The electronic component according to claim 7, wherein
the second external terminal is inside an outer edge of the main surface when viewed in a direction perpendicular to the main surface.

10. The electronic component according to claim 1, wherein
the coil includes a first inductor wiring extending along the main surface and a second inductor wiring extending along the main surface and electrically connected to the first inductor wiring,
the first inductor wiring and the second inductor wiring are side by side in a direction perpendicular to the main surface, and
a distance between the first inductor wiring and the second inductor wiring in a direction perpendicular to the main surface is smaller than a thickness of the first inductor wiring in a direction perpendicular to the main surface.

11. The electronic component according to claim 10, wherein
the coil further includes a connection wiring that connects the first inductor wiring and the second inductor wiring to each other, and
the connection wiring extends in a direction perpendicular to the main surface.

12. The electronic component according to claim 1, wherein
the semiconductor substrate is entirely configured by the low-resistance portion.

13. The electronic component according to claim 1, further comprising:
a dielectric portion and an electrode portion:
wherein the low-resistance portion is exposed from at least a portion of the main surface,
the dielectric portion is on the low-resistance portion and the electrode portion is on the dielectric portion, and
a capacitor element is configured by the low-resistance portion, the dielectric portion, and the electrode portion.

14. The electronic component according to claim 13, wherein
the coil includes a first inductor wiring extending along the main surface and a second inductor wiring extending along the main surface and electrically connected to the first inductor wiring,
the first inductor wiring and the second inductor wiring are side by side in a direction perpendicular to the main surface, and
a thickness of the electrode portion in a direction perpendicular to the main surface is smaller than a thickness of the first inductor wiring in a direction perpendicular to the main surface.

15. The electronic component according to claim 1, wherein
a portion of the semiconductor substrate is configured by the low-resistance portion, and
the semiconductor substrate includes a diode element in a region other than a region where the low-resistance portion is disposed.

16. The electronic component according to claim 1, further comprising:
a wiring portion including a conductive material which is the same as the conductive material of the coil and the wiring portion being electrically isolated from the coil.

17. A method of manufacturing the electronic component according to claim 1, comprising:
forming the low-resistance portion in the semiconductor substrate; and
forming the coil after forming the low-resistance portion.

18. The electronic component according to claim 3, wherein
the organic insulating layer is at least one of between adjacent turns of the coil and in an inner diameter portion of the coil.

19. The electronic component according to claim 2, further comprising:
a first external terminal that is electrically connected to the coil and disposed along a plane parallel to the main surface.

20. The electronic component according to claim 2, further comprising:
a second outer terminal,
wherein the low-resistance portion is exposed from at least a portion of an outer surface of the semiconductor substrate,
the second outer terminal is on the portion of the outer surface where the low-resistance portion is exposed, and
the second outer terminal is connected to the low-resistance portion.
